(19) United States
(12) Patent Application Publication
(10) Pub. No.: US 2026/0172023 A1
(43) Pub. Date: Jun. 18, 2026

(54) DUAL-GATE SWITCH DEVICE

(71) Applicant: ALPHA AND OMEGA SEMICONDUCTOR INTERNATIONAL LP, ONTARIO (CA)

(72) Inventors: HUI YE, SAN JOSE, CA (US); JIAN YIN, SAN RAMON, CA (US); LIN CHEN, SAN JOSE, CA (US); KUANG MING CHANG, FREMONT, CA (US); ZIWEI YU, CUPERTINO, CA (US)

(21) Appl. No.: 18/985,531

(22) Filed: Dec. 18, 2024

(51) Int. Cl. H03K 17/16; H02M 1/00; H02M 3/158; H03K 17/284

(52) U.S. Cl. CPC H03K 17/163; H02M 1/0058; H02M 3/158; H03K 17/284; H03K 2217/0063; H03K 2217/0072

(57) ABSTRACT

A switch device includes a first transistor, a second transistor, a first driver, and a second driver. The first transistor includes a first terminal, a second terminal, and a control terminal. The second transistor includes a first terminal coupled to the first terminal of the first transistor, a second terminal coupled to the second terminal of the first transistor, and a control terminal. The first driver is coupled to the control terminal of the first transistor and configured to drive the first transistor. The second driver is coupled to the control terminal of the second transistor and configured to drive the second transistor. During a first period in which the first transistor and the second transistor are to be turned on, the first transistor is turned on before the second transistor is turned on.

### TECHNICAL FIELD

The present disclosure relates to a switch device and a method for operating switch device, and more particularly, to a dual-gate switch device.

### DISCUSSION OF THE BACKGROUND

Switching devices are integral to modern power electronics, such as buck converters, boost converters, and switched capacitor converters, for enabling efficient voltage conversion and regulation. Generally, the power efficiency of switch devices is primarily affected by their switching losses and conduction losses.

Switching loss occurs during the transition periods when a switch (such as a MOSFET) turns on or off. These losses are associated with the time it takes for the switch to transition between its on and off states. During these transitions, both voltage across and current through the switch are non-zero, leading to power dissipation. Conduction loss, on the other hand, occurs when the switch is in the on state and current flows through it. This loss is primarily due to the on-state resistance (Rds(on)) for MOSFETs.

However, it can be difficult to reduce the switching loss and the conduction loss of the switch device at the same time. For instance, a switch device designed to have low on-state resistance (to minimize conduction loss) might have a larger gate charge, which can increase the switching losses due to the higher energy required to charge and discharge the gate capacitance during each switching cycle. Conversely, a switch device optimized for low switching loss might have a higher on-state resistance, leading to increased conduction losses. Therefore, designing a high efficiency switch device that remains an issue to be solved.

### SUMMARY

One aspect of the present disclosure provides a switch device. The switch device includes a first transistor, a second transistor, a first driver and a second driver. The transistor includes a first terminal, a second terminal, and a control terminal. The second transistor includes a first terminal coupled to the first terminal of the first transistor, a second terminal coupled to the second terminal of the first transistor, and a control terminal. The first driver is coupled to the control terminal of the first transistor and configured to drive the first transistor. The second driver is coupled to the control terminal of the second transistor and configured to drive the second transistor. During a first period in which the switch device is turned on, the first transistor is turned on before the second transistor is turned on.

Another aspect of the present disclosure provides a voltage converter. The voltage converter includes the switch device aforementioned, a low side switch, a third driver, an energy storage component, and a switch controller. The first transistor and the second transistor of the switch device are configured as a high side switch. The low side switch includes a third transistor, and the third transistor includes a first terminal coupled to the second terminal of the first transistor, a second terminal, and a control terminal. The third driver is coupled to the control terminal of the third transistor and configured to drive the third transistor. The energy storage component is coupled to the high side switch and the low side switch. The switch controller is configured to generate pulse-width modulation (PWM) signals to control the high side switch and the low side switch so as to charge and discharge the energy storage component, thereby enabling the voltage converter to provide an output voltage converted according to an input voltage.

Another aspect of the present disclosure provides a semiconductor integrated circuit (IC). The semiconductor IC includes a source contact, a drain contact, a first gate contact, a second gate contact, a first transistor, and a second transistor. The first transistor includes a first terminal coupled to the source contact, a second terminal coupled to the drain contact, and a control terminal coupled to the first gate contact. The second transistor includes a first terminal coupled to the source contact, a second terminal coupled to the second terminal coupled to the drain contact, and a control terminal coupled to the second gate contact. During a first period in which the first transistor and the second transistor are to be turned on, the first transistor is turned on first before the second transistor is turned on.

Another aspect of the present disclosure provides a method for operating a switch device. The switch device includes a first transistor and a second transistor. The first transistor includes a first terminal, a second terminal, and a control terminal, the second transistor includes a first terminal coupled to the first terminal of the first transistor, a second terminal coupled to the second terminal of the first transistor, and a control terminal. The method includes, in response to a first signal edge of a source PWM signal, turning on the first transistor and turning on the second transistor after the first transistor is turned on.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures.

FIG. 1 shows a buck converter according to a comparative embodiment of the present disclosure.

FIG. 2 shows a timing diagram of the buck converter in FIG. 1.

FIG. 3 shows a buck converter with an adoption of a switch device according to one embodiment of the present disclosure.

FIG. 4 shows a timing diagram of the buck converter in FIG. 3 according to one embodiment of the present embodiment.

FIG. 5 shows a buck converter according to another embodiment of the present disclosure.

FIG. 6 shows a timing diagrams of the PWM signals in FIG. 5 according to one embodiment of the present disclosure.

FIG. 7 shows a semiconductor IC according to one embodiment of the present disclosure.

FIG. 8 shows a flow chart of a method for operating a switch device according to one embodiment of the present disclosure.

### DETAILED DESCRIPTION

The following description accompanies drawings, which are incorporated in and constitute a part of this specification, and which illustrate embodiments of the disclosure, but the disclosure is not limited to the embodiments. In addition, the following embodiments can be properly integrated to complete another embodiment.

References to “one embodiment,” “an embodiment,” “exemplary embodiment,” “other embodiments,” “another embodiment,” etc. indicate that the embodiment(s) of the disclosure so described may include a particular feature, structure, or characteristic, but not every embodiment necessarily includes the particular feature, structure, or characteristic. Further, repeated use of the phrase “in the embodiment” does not necessarily refer to the same embodiment, although it may.

In order to make the present disclosure completely comprehensible, detailed steps and structures are provided in the following description. Obviously, implementation of the present disclosure does not limit special details known by persons skilled in the art. In addition, known structures and steps are not described in detail, so as not to unnecessarily limit the present disclosure. Preferred embodiments of the present disclosure will be described below in detail. However, in addition to the detailed description, the present disclosure may also be widely implemented in other embodiments. The scope of the present disclosure is not limited to the detailed description, and is defined by the claims.

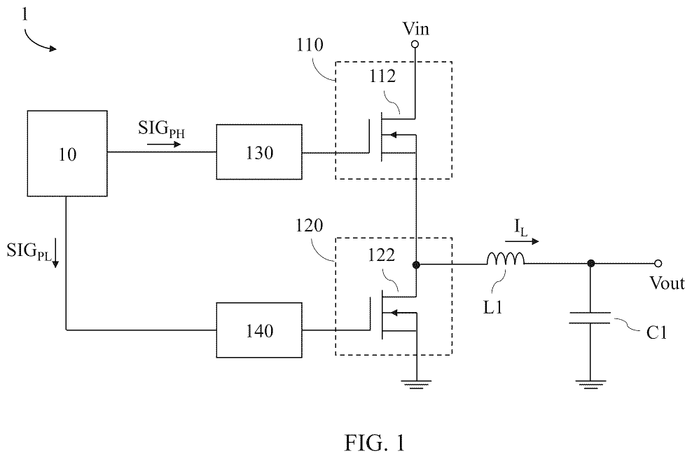

FIG. 1 shows a buck converter 1 according to a comparative embodiment of the present disclosure. The buck converter 1 includes a high side switch 110, a low side switch 120, a driver 130, a driver 140, a switch controller 10, an inductor L1 and a capacitor C1.

The buck converter 1 can convert an input voltage Vin into an output voltage Vout that is lower than the input voltage Vin. As shown in FIG. 1, the high side switch 110 includes a transistor 112, and the transistor 112 includes a first terminal coupled to the input voltage Vin, a second terminal, and a control terminal. The low side switch 120 includes a transistor 122, and the transistor 122 includes a first terminal coupled to the second terminal of the transistor 112, a second terminal coupled to a system voltage (e.g., the ground voltage), and a control terminal. The driver 130 is coupled to the control terminal of the transistor 112 for driving the transistor 112 according to the pulse-width modulation (PWM) signal SIG_{PH} generated by the switch controller 10, and the driver 140 is coupled to the control terminal of the transistor 122 for driving the transistor 122 according to the PWM signal SIG_{LH} generated by the switch controller 10.

The switch controller 10 can generate the PWM signals SIG_{PH} and SIG_{PL} to the drivers 130 and 140 for controlling the high side switch 110 and the low side switch 120 so as to charge and discharge the inductor L1 in an alternating manner, thereby enabling the buck converter 1 to provide the output voltage Vout. In some cases, the switch controller 10 may be a logic circuit that can only generate the PWM signals SIG_{PH} and SIG_{PL} with lower voltages and smaller driving capability, which may not be able to turn on or turn off the transistors 112 and 122 effectively. Therefore, the driver 130 and 140 are added to enhance the PWM signals SIG_{PH} and SIG_{PL}, (for example, by shifting the voltage levels of the PWM signals SIG_{PH} and SIG_{PL} to a higher level and/or providing a higher current rating) so as to fully control the transistors 112 and 122.

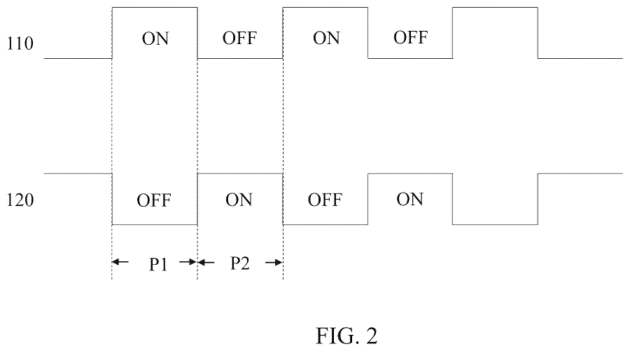

FIG. 2 shows a timing diagram of the buck converter 1. As shown in FIG. 2, during a first period P1, the transistor 112 of the high side switch 110 is turned on and the transistor 122 of the low side switch 120 is turned off. In such case, the inductor L1 is charged through the high side switch 110, and the inductor L1 would resist the sudden increase of the charging current and induce a reversed voltage on the output path that lowers the output voltage Vout.

During a second period P2, the transistor 112 of the high side switch 110 is turned off and the transistor 122 of the low side switch 120 is turned on, so the inductor L1 is discharged through the low side switch 120. In such case, the inductor L1 would reverse its polarity so as to resist the sudden drop of the current, thereby sustaining the continuity of the current I_{L}. Additionally, as the inductor L1 works to ensure the continuity of the current I_{L}, the capacitor C1 can help to smooth out the ripples of the output voltage Vout.

Generally, to provide the desired output voltage stably, the switching frequency of the high side switch 110 and the low side switch 120 can be up to 100kHz or higher. Therefore, the switching loss can be crucial for the overall power efficiency of the buck converter 1. In addition, the switching loss caused by the high side switch 110 is more significant for the overall loss than the switching loss caused by the low side switch 120. This is because the high side switch 110 typically has to withstand a higher cross voltage during transitions. To reduce the switching loss, one strategy is to decrease the die size of the transistor 112 in the high side switch 110, which lowers the parasitic capacitances and reduces the gate charges (i.e., Qgd) that required for switching. However, the smaller die size may increase the turn-on resistance of the transistor 112, which results in greater conduction loss. Such challenge of balancing the conduction loss and switching loss is also encountered in other similar switching applications, such as boost converters and switched capacitor converters.

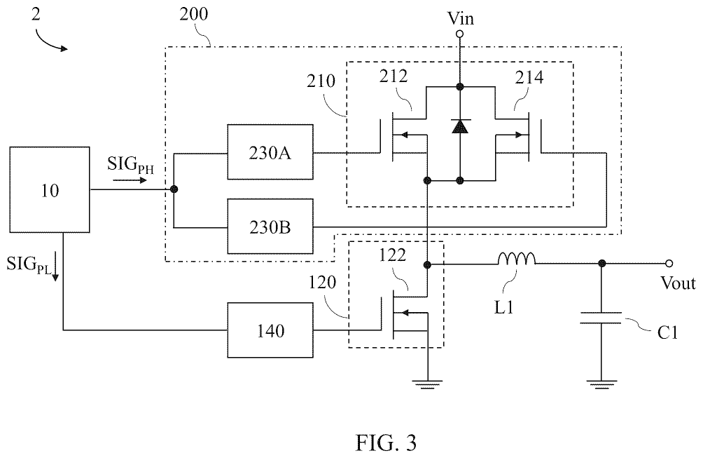

FIG. 3 shows a buck converter 2 with the adoption of a switch device 200 according to one embodiment of the present disclosure. The switch device 200 includes two transistors 212 and 214 along with two drivers 230A and 230B, where the transistors 212 and 214 are together configured as the high side switch 210 of the buck converter 2.

As shown in FIG. 3, the transistor 212 includes a first terminal coupled to the input voltage Vin, a second terminal, and a control terminal. The transistor 214 includes a first terminal coupled to the first terminal of the transistor 212, a second terminal coupled to the second terminal of the transistor 212, and a control terminal. In other words, the transistor 212 and the transistor 214 are coupled in parallel. However, the transistor 212 and the transistor 214 are driven by different drivers 230A and 230B. In the present embodiment, the driver 230A is coupled to the control terminal of the transistor 212 for driving the transistor 212, and the driver 230B is coupled to the control terminal of the transistor 214 for driving the transistor 214. Furthermore, in some embodiments, the total die size of the two transistors 212 and 214 can be same as the die size of the transistor 112 adopted in the buck converter 1 shown in FIG. 1. For example, each of the transistors 212 and 214 may have a die size half of the die size of the transistor 112. In the present embodiment, when turning on the high side switch 210, the transistor 212 and the transistor 214 can be turned on sequentially to reduce the switching loss without increasing the conduction loss.

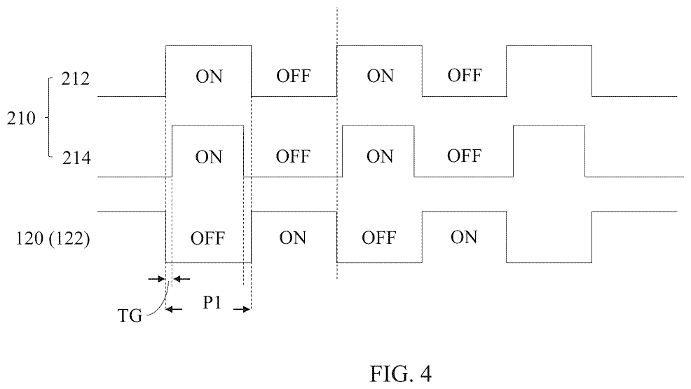

FIG. 4 shows a timing diagram of the buck converter 2 according to one embodiment of the present embodiment. As shown in FIG. 4, when turning on the high side switch 210 during the period P1, the transistor 212 can be turned on before the transistor 214 is turned on. In such case, since the transistor 212 has a smaller die size than that of the transistor 112, the switching loss of the high side switch 210 can be reduced. Also, after the transistor 212 is turned on, the transistor 214 can be turned on so as to reduce the conduction loss. Consequently, the switch device 200 is able to provide lower switching loss without increasing the conduction loss, and the overall power efficiency of the buck converter 2 can be improved. Similarly, when turning off the switch device 200 during the period P2, the transistor 214 can be turned off before the transistor 212 is turned off, thereby reducing the switching loss.

In some embodiments, the switching sequence between the transistors 212 and 214 can be achieved by allowing the drivers 230A and 230B to have different driving capability (i.e., source/sink capability). For example, the driving capability of the driver 230A can be greater than the driving capability of the driver 230B. In such case, in response to a same signal edge (e.g., a rising edge) of the source PWM signal SIG_{PH}, the driver 230A is able to turn on the transistor 212 before the driver 230B turns on the transistor 214. In some embodiments, the driving capability of the driver 230A can be two times greater than the driving capability of the driver 230B so as to ensure the desired switching sequence between the transistors 212 and 214. However, the present disclosure is not limited thereto.

In some embodiments, the desired switching sequence between the transistors 212 and 214 can be achieved by allowing the drivers 230A and 230B to have different driving voltage. For example, the driving voltage generated by the driver 230A for turning on the transistor 212 can be higher than the driving voltage generated by the driver 230B for turning on the transistor 214. In such case, in response to a same signal edge (e.g., a rising edge) of the source PWM signal SIG_{PH}, the driver 230A is able to turn on the transistor 212 before the driver 230B turns on the transistor 214.

Furthermore, in some embodiments, the desired switching sequence between the transistors 212 and 214 can also be achieved by allowing the transistors 212 and 214 to have different threshold voltages. For example, a threshold voltage of the transistor 212 can be smaller than a threshold voltage of the transistor 214. In such case, even if the driver 230A and the driver 230B, which have the same driving capability, drive the transistors 212 and 214 according to the same PWM signal SIG_{PH}, the transistor 212 having the lower threshold voltage can be turned on first, and the transistor 214 having the higher threshold voltage can be turned on later.

In some embodiments, the aforementioned approaches of adjusting the driving capabilities of the drivers 230A and 230B, adjusting the driving voltages of the drivers 230A and 230B, and adjusting the threshold voltages of the transistors 212 and 214 can be adopted individually or in combination. For example, in some embodiments, if the threshold voltage of the transistor 212 is slightly lower than the threshold voltage of the transistor 214 (e.g., the threshold voltage of the transistor 212 is 1.4V and the threshold voltage of the transistor 214 is 1.8V), then the driver 230A may have its driving voltage or driving capability slightly higher (e.g., 1 to 1.5 times more) than that of the driver 230B. On the other hand, if the threshold voltage of the transistor 212 is quite lower than the threshold voltage of the transistor 214 (e.g., the threshold voltage of the transistor 212 is 1.4V and the threshold voltage of the transistor 214 is greater than 1.8V), then the driver 230A may have its driving voltage or driving capability similar to that of the driver 230B, thereby avoiding an excessive increase in the time gap TG between the time point that the transistor 212 is turned on and the time point that the transistor 214 is turned on. In some embodiments, the time gap TG should be kept within 10 ns. However, the present disclosure is not limited thereto.

It should also be noted that, since the transistor 214 is designed to be turned on after the transistor 212 is turned on in the switch device 200, the transistor 214 should be turned on mostly in a soft switching mode. Therefore, the requirement for the driving capability of the driver 230B can be lower than that of the driver 230A. In some embodiments, differences between the driving capabilities of the drivers 230A and 230B can be realized by manufacturing the drivers 230A and 230B with different die sizes. For example, the die size of the driver 230B can be smaller than the die size of the driver 230A. In addition, the difference between die sizes (or the driving capabilities) of the drivers 230A and 230B can help to secure the desired switching sequence between the transistors 212 and 214 as aforementioned.

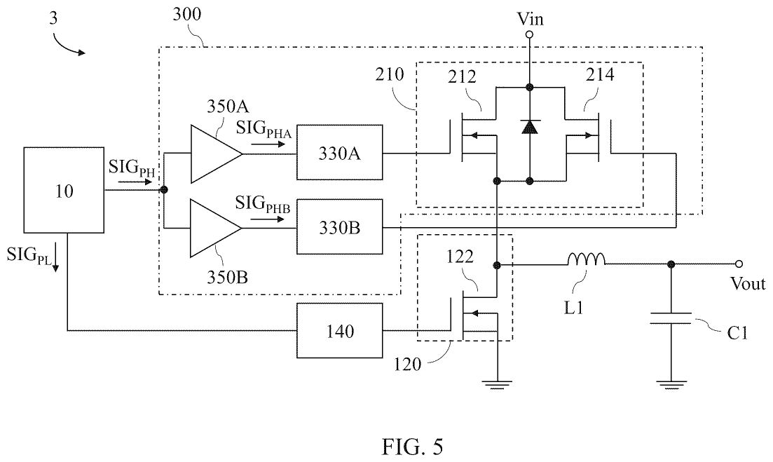

In some embodiments, the switching sequence can be achieved by generating different PWM signals for the transistors 212 and 214 by utilizing proper delay logics. FIG. 5 shows a buck converter 3 according to another embodiment of the present disclosure. The buck converter 3 is different from the buck converter 2 in that the drivers 330A and 330B in the switch device 300 can receive different PWM signals SIG_{PHA} and SIG_{PHB}. Specifically, the driver 330A receives the PWM signal SIG_{PHA} for driving the transistor 212, and the driver 330B receives the PWM signal SIG_{PHB} for driving the transistor 214.

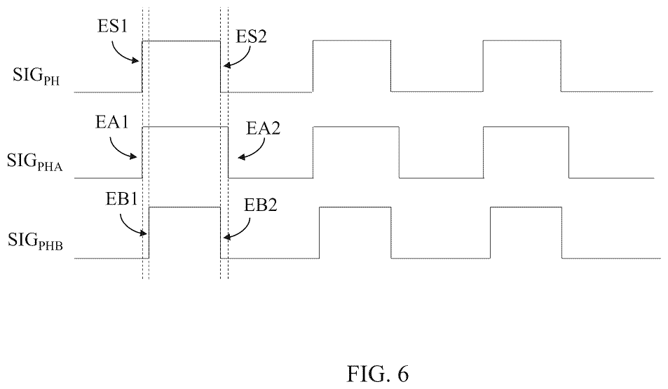

FIG. 6 shows a timing diagrams of the PWM signals SIG_{PH}, SIG_{PHA} and SIG_{PHB} according to one embodiment of the present disclosure. In the present embodiment, the transistors 212 and 214 are N-type transistors having positive threshold voltage, and thus, the transistors 212 and 214 are turned on when the PWM signals SIG_{PHA} and SIG_{PHB} are at the high voltage, and are turned off when the PWM signals SIG_{PHA} and SIG_{PHB} are at the low voltage. However, the present disclosure is not limited thereto. In some other embodiments, the transistor 212 and 214 may be P-type transistors, and the PWM signals SIG_{PH}, SIG_{PHA} and SIG_{PHB} may have waveforms opposite to those shown in FIG. 6.

As shown in FIG. 6, the signal edge EA1 of the PWM signal SIG_{PHA} for turning on the transistor 212 leads the signal edge EB1 of the PWM signal SIG_{PHB} for turning on the transistor 214. Correspondingly, the transistor 212 can be turned on before the transistor 214 is turned on.

Furthermore, in the present embodiment, the signal edge EB2 of the PWM signal SIG_{PHB} for turning off the transistor 214 leads the signal edge EA2 of the PWM signal SIG_{PHA} for turning off the transistor 212. Therefore, the transistor 214 can be turned off before the transistor 212 is turned off.

As shown in FIG. 5, the PWM signals SIG_{PHA} and SIG_{PHB} can be generated by the delay elements 350A and 350B according to the source PWM signal SIG_{PH} generated by the switch controller 10. In the present embodiment, the delay element 350A can delay the signal edge ES1 of the source PWM SIG_{PH} for turning on the high side switch 210 so as to generate the PWM signal SIG_{PHB}, and the delay element 350B can delay the signal edge ES2 of the source PWM SIG_{PH} for turning off the high side switch 210 so as to generate the PWM signal SIG_{PHA}. Therefore, when turning on the high side switch 210, the transistor 212 can be turned on before the transistor 214 is turned on. Also, when turning off the high side switch 210, the transistor 214 can be turned off before the transistor 212 is turned off.

In the present embodiment, since the transistors 212 and 214 are both N-type transistors, the signal edges EA1, EB1, and ES1 for turning on the transistors 212 and 214 are referred to the rising edges and the signal edges EA2, EB2, and ES2 for turning off the transistors 212 and 214 are referred to the falling edges as shown in FIG. 6. However, the present disclosure is not limited thereto. In some other embodiments, the transistors 212 and 214 may both be P-type transistors, and the signal edges for turning on the transistors 212 and 214 may be referred to the falling edges while the signal edges for turning off the transistors 212 and 214 may be referred to the rising edges.

Furthermore, in some embodiments, the transistor 214 can also be turned off after the transistor 212 is turned off. That is, as long as one of the transistors 212 and 214 is turned on faster than the other one, and one of the transistors 212 and 214 is turned off faster than the other one, then the goal of reducing switching loss can be achieved. Therefore, in some embodiments, the driver 330A for controlling the transistor 212 may receive the source PWM signal SIG_{PH}, and the driver 330B for controlling the transistor 214 may receive a PWM signal that is generated by delaying all the signal edges of the source PWM signal SIG_{PH}.

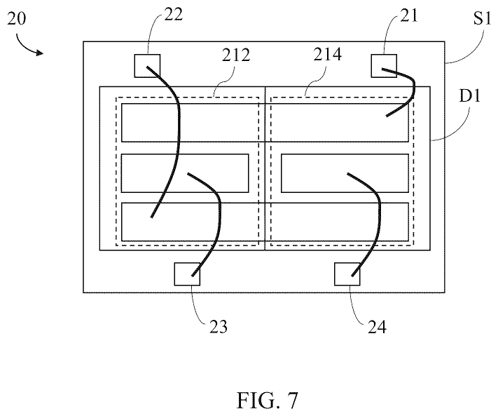

In some embodiments, the transistors 212 and 214 can be formed on the same die and can be packaged as one semiconductor integrated circuit (IC). FIG. 7 shows a semiconductor IC 20 according to one embodiment of the present disclosure. The semiconductor IC 20 includes the transistors 212 and 214, a source contact 21, a drain contact 22, a first gate contact 23, and a second gate contact 24. In the present embodiment, the transistors 212 and 214 are formed on the die D1, and the die D1 is disposed on a substrate S1.

Furthermore, the first terminals of the transistors 212 and 214 on the active area of the die D1 can be coupled to the source contact 21, and the second terminals of the transistors 212 and 214 on the active area of the die D1 can be coupled to the drain contact 22. Also, the control terminal of the transistor 212 on the active area of the die D1 can be coupled to the first gate contact 23, and the control terminal of the transistor 214 on the active area of the die D1 can be coupled to the second gate contact 24. That is, the two transistors 212 and 214 can have a common source, a common drain, and separate gates. The separate gates are individually accessible through the drivers 230A and 230B (or 330A and 330B). In some embodiments, the transistors 212 and 214 can be of the same type (e.g., N-type transistors), and can be manufactured on the same die with the same processes.

In the present embodiment, the source contact 21, the drain contact 22, and the gate contacts 23 and 24 can be parts of lead-frames that are served as the input/output pins of the semiconductor IC 20. In such case, the terminals of the transistors 212 and 214 on the die D1 can be coupled to the corresponding contacts via bonding wires. However, the present disclosure is not limited thereto. In some embodiments, other types of package may be applied, and the forms of connections between the terminals of the transistors 212 and 214 on the die D1 and the corresponding contacts can be different from those shown in FIG. 7.

In addition, although the switch devices 200 and 300 are adopted in the buck converters 2 and 3 for charging the inductor L1, the switch devices 200 and 300 may also be adopted by other types of switching voltage converters, such as boost converters, switch capacitor converters, etc.. In such case, the switch devices 200 and 300 may be adopted for charging (or discharging) other types of energy storage component, such as capacitors. Furthermore, in some embodiments, the low side switch 120 and the driver 140 may also be replaced by the switch device 200 or 300 for further reducing the switching loss of the voltage converter. Alternatively, instead of adopting the low side switch 120 and the driver 140 as a synchronous voltage converter, in some embodiments, the low side switch 120 and the driver 140 may also be replaced by a diode as an asynchronous voltage converter.

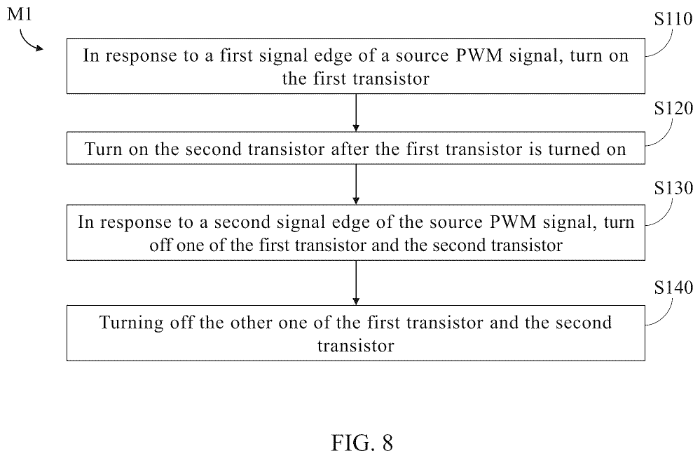

FIG. 8 shows a flow chart of a method M1 for operating a switch device according to one embodiment of the present disclosure. In some embodiments, the method M1 can be applied to operate the switch device 200.

According to the method M1, in response to a signal edge (e.g., a rising edge) of the PWM signal SIG_{PH} for controlling the switch device 200, the transistor 212 can be turned on first in step S110, and the transistor 214 can be turned on in step S120 after the transistor 212 is turned on. By turning on the transistor 212 with a smaller die size first, the gate charge required for turning on the switch device 200 can be reduced, thereby reducing the switching loss of the switch device 200. Also, by turning on the transistor 214 after the transistor 212 is turned on, the on-state resistance of the switch device 200 can be reduced, thereby reducing the conduction loss of the switch device 200. As a result, the power efficiency of the switch device 200 can be improved.

Similarly, in response to another signal edge (e.g., a falling edge) of the PWM signal SIG_{PH}, one of the transistors 212 or 214 can be turned off first in step S130, and the other transistor can be turned off afterward in step S140. Thus, the switching loss for turning off the switch device 200 can also be reduced.

In some embodiments, steps S110 to S140 can be achieved by allowing the transistors 212 and 214 to have different threshold voltages, and/or allowing the drivers 230A and 230B to have different driving capabilities or different driving voltages.

In some embodiments, the method M1 can also be applied to operate the switch device 300. In such case, steps S110 to S140 can be achieved by using delay logics, such as delay elements 350A and 350B, to generate different PWM signals to the control terminals of the transistors 212 and 214. For example, the method M1 may further includes generating the PWM signal SIG_{PHB} to the control terminal of the transistors 214 by delaying the signal edges (e.g., the rising edges) of the source PWM signal SIG_{PH} for turning on the switch device 200, and generating the PWM signal SIG_{PHA} to the control terminal of the transistors 212 by delaying the signal edges (e.g., the falling edges) of the source PWM signal SIG_{PH} for turning off the switch device 200. As a result, when turning on the switch device 200, the transistor 212 can be turned on faster than the transistor 214. Also, when turning off the switch device 200, the transistor 212 can be turned off faster than the transistor 214.

In summary, the switch devices, the voltage converters and the methods for operating the switch devices provided by the embodiments of the present disclosures allows to sequentially turn on/off the transistors in the switch, so that the switching loss can be reduced without increasing the conduction loss. As a result, the power efficiency of the switch devices can be improved.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods and steps.

What is claimed is:

1. A switch device comprising:
a first transistor comprising a first terminal, a second terminal, and a control terminal; and
a second transistor comprising a first terminal coupled to the first terminal of the first transistor, a second terminal coupled to the second terminal of the first transistor, and a control terminal; and
a first driver coupled to the control terminal of the first transistor and configured to drive the first transistor; and
a second driver coupled to the control terminal of the second transistor and configured to drive the second transistor;
wherein during a first period in which the switch device is turned on, the first transistor is turned on before the second transistor is turned on.

2. The switch device of claim 1, wherein:
a threshold voltage of the first transistor is smaller than a threshold voltage of the second transistor.

3. The switch device of claim 1, wherein a driving capability of the first driver is greater than a driving capability of the second driver.

4. The switch device of claim 1, wherein a die size of the first driver is greater than a die size of the second driver.

5. The switch device of claim 1, wherein a first driving voltage generated by the first driver for turning on the first transistor is greater than a second driving voltage generated by the first driver for turning the first transistor.

6. The switch device of claim 1, wherein:
the first driver is configured to receive a first pulse-width modulation (PWM) signal to drive the first transistor;
the second driver is configured to receive a second PWM signal to drive the second transistor; and
a signal edge of the first PWM signal for turning on the first transistor leads a signal edge of the second PWM signal for turning on the second transistor.

7. The switch device of claim 8, further comprising:
a first delay element configured to generate the second PWM signal according to a source PWM signal by delaying a signal edge of the source PWM for turning on the first transistor and the second transistor.

8. The switch device of claim 9, further comprising:
a second delay element configured to generate the first PWM signal according to the source PWM signal by delaying a signal edge of the source PWM signal for turning off the first transistor and the second transistor.

9. The switch device of claim 1, wherein during a second period in which the switch device is turned off, one of the first transistor and the second transistor is turned off before the other one is turned off.

10. A voltage converter comprising:
the switch device of claim 1, wherein the first transistor and the second transistor are configured as a high side switch;
a low side switch comprising a third transistor, wherein the third transistor comprises a first terminal coupled to the second terminal of the first transistor, a second terminal, and a control terminal;
a third driver coupled to the control terminal of the third transistor and configured to drive the third transistor;
an energy storage component coupled to the high side switch and the low side switch; and
a switch controller configured to generate pulse-width modulation (PWM) signals to control the high side switch and the low side switch so as to charge and discharge the energy storage component, thereby enabling the voltage converter to provide an output voltage converted according to an input voltage.

11. A semiconductor integrated circuit (IC) comprising:
a source contact;
a drain contact;
a first gate contact;
a second gate contact;
a first transistor comprising a first terminal coupled to the source contact, a second terminal coupled to the drain contact, and a control terminal coupled to the first gate contact; and
a second transistor comprising a first terminal coupled to the source contact, a second terminal coupled to the second terminal coupled to the drain contact, and a control terminal coupled to the second gate contact; and
wherein during a first period in which the first transistor and the second transistor are to be turned on, the first transistor is turned on first before the second transistor is turned on.

12. The semiconductor IC of claim 11, wherein a threshold voltage of the first transistor is smaller than a threshold voltage of the second transistor.

13. The semiconductor IC of claim 11, wherein a die size of the first transistor equals to a die size of the second transistor.

14. The semiconductor IC of claim 11, wherein during a second period in which the first transistor and the second transistor are to be turned off, one of the first transistor and the second transistor is turned off before the other one is turned off.

15. A method for operating a switch device, wherein the switch device comprises a first transistor and a second transistor, the first transistor comprises a first terminal, a second terminal, and a control terminal, the second transistor comprises a first terminal coupled to the first terminal of the first transistor, a second terminal coupled to the second terminal of the first transistor, and a control terminal, and the method comprising:
in response to a first signal edge of a source pulse-width modulation (PWM) signal:
turning on the first transistor; and
turning on the second transistor after the first transistor is turned on.

16. The method of claim 15, wherein a driving capability for driving the first transistor is greater than a driving capability for driving the second transistor.

17. The method of claim 15, further comprising:
generating a first pulse-width modulation (PWM) signal to the control terminal of the first transistor according to the source PWM signal; and
generating a second PWM signal to the control terminal of the second transistor according to the source PWM signal;
wherein a signal edge of the first PWM signal for turning on the first transistor leads a signal edge of the second PWM signal for turning on the second transistor.

18. The method of claim 17, wherein generating the second PWM signal to the control terminal of the second transistor according to the source PWM signal comprises:
delaying the first signal edge of the source PWM signal for turning on the switch device.

19. The method of claim 18, wherein generating the first PWM signal to the control terminal of the first transistor according to the source PWM signal comprises:
delaying a second signal edge of the source PWM signal for turning off the switch device.

20. The method of claim 15, further comprising in response to a second signal edge of the source pulse-width modulation signal:
turning off one of the first transistor and the second transistor; and
turning off the other one of the first transistor and the second transistor;
wherein the second signal edge and the first edge have different transition directions.
